(19) United States
(12) Patent Application Publication
(10) Pub. No.: US 2017/0280569 A1
(43) Pub. Date: Sep. 28, 2017

(54) EXTENDED PADS TO EASE REWORK FOR BTC AND BGA TYPE TECHNOLOGY

(71) Applicant: ALCATEL-LUCENT CANADA INC., Ottawa (CA)

(72) Inventors: James M. SCHRIEL, Kanata (CA); Alex L. CHAN, Nepean (CA); Paul J. BROWN, Wakefield (CA)

(73) Assignee: ALCATEL-LUCENT CANADA, INC.

(21) Appl. No.: 15/082,682

(22) Filed: Mar. 28, 2016

(51) Int. Cl. H05K 3/34; G06F 17/50; H05K 3/00; H05K 1/18; H05K 1/11

(52) U.S. Cl. CPC H05K 3/3436; H05K 1/181; H05K 1/111; H05K 3/0005; G06F 17/5072; H05K 2201/10719; H05K 2201/10734; G06F 2217/38

(57) ABSTRACT

Various exemplary embodiments relate to a printed circuit board (PCB) for electrically connecting a surface mount component including: a plurality of metal pads on the surface of one side of the PCB corresponding to connection points on the component, wherein at least a portion of the plurality of metal pads have stubs which extend outside the boundary of the surface mount component when the surface mount component is mounted to the PCB; and wherein the stubs have sufficient thermal conductivity to facilitate at least one of the set of dismounting and reattaching of the surface mount component.

### TECHNICAL FIELD

Various exemplary embodiments disclosed herein relate generally to circuit board pad design.

### BACKGROUND

A land grid array (LGA) is a type of surface-mount packaging (a chip carrier) used for integrated circuits. LGA packages are used to permanently mount devices such as microprocessors. A LGA can provide more interconnection pins than can be put on a dual in-line or flat package. The whole bottom surface of the device can be used, instead of just the perimeter. The leads are also on average shorter than with a perimeter-only type, leading to better performance at high speeds. A ball grid array (BGA) is a specific type of LGA that uses solder balls to facilitate the connection between the device and a circuit board.

### SUMMARY

Some simplifications and omissions may be made in the following summary, which is intended to highlight and introduce some aspects of the various exemplary embodiments, but not to limit the scope of the invention. Detailed descriptions of a preferred exemplary embodiment adequate to allow those of ordinary skill in the art to make and use the inventive concepts will follow in later sections.

Various exemplary embodiments relate to a printed circuit board (PCB) for electrically connecting a surface mount component including: a plurality of metal pads on the surface of one side of the PCB corresponding to connection points on the component, wherein at least a portion of the plurality of metal pads have stubs which extend outside the boundary of the surface mount component when the surface mount component is mounted to the PCB; and wherein the stubs have sufficient thermal conductivity to facilitate at least one of the set of dismounting and reattaching of the surface mount component.

Various exemplary embodiments relate to a method of manufacturing a printed circuit board (PCB) assembly for electrically connecting a surface mount component, including the steps of: forming a plurality of metal pads on the surface of one side of the PCB corresponding to connection points on the component, wherein at least a portion of the plurality of metal pads have extensions which extend outside the boundary of the surface mount component when the surface mount component is mounted to the PCB; wherein the extensions have sufficient thermal conductivity to facilitate at least one of the set of dismounting and reattaching of the surface mount component; and conductively attaching the component to the plurality of metal pads on the PC.

Various exemplary embodiments relate to a computer aided design tool implemented on a computing device for accommodating a resoldering of a land grid array printed circuit board (PCB) for use with mounting a component including: a design tool mode configured to identify a placement of components on the PCB and to create a corresponding array of metal pads on one side of the PCB, wherein the metal pads extend outside the boundary of the component when the component is mounted to the PCB; a design tool mode configured to create thermal connections between the metal pads and the extensions have a solder resist barrier portion between the pads and the extensions, and the extensions are also portions of signal carrying lines.

Various exemplary embodiments relate to printed circuit board (PCB) for electrically connecting a surface mount component including: a plurality of metal pads on the surface of one side of the PCB corresponding to connection points on the component, wherein at least a portion of the plurality of metal pads have extensions which extend outside the boundary of the surface mount component when the surface mount component is mounted to the PCB and wherein the extensions have sufficient thermal conductivity to facilitate at least one of the set of dismounting and reattaching of the surface mount component; a signal line connected to one of the plurality of extensions; and a layer of solder resist covering the signal line, wherein the layer of solder resist has an aperture over the extensions

### BRIEF DESCRIPTION OF THE DRAWINGS

In order to better understand various exemplary embodiments, reference is made to the accompanying drawings, wherein:

FIG. 1 illustrates a bottom view of an exemplary component for mounting on a PCB;

FIG. 2A illustrates a top view of a related art PCB;

FIG. 2B illustrates a top view of related art PCB with attached component;

FIG. 3A illustrates a top view of exemplary PCB;

FIG. 3B illustrates a top view of exemplary PCB with attached component;

FIG. 4A illustrates a top view of exemplary PCB;

FIG. 4B illustrates a top view of exemplary PCB with attached component;

FIG. 5A illustrates a top view of exemplary PCB;

FIG. 5B illustrates a top view of exemplary PCB with attached component;

FIG. 6 illustrates embodiment; and

FIG. 7 illustrates exemplary method for resoldering.

### DETAILED DESCRIPTION

The description and drawings presented herein illustrate various principles. It will be appreciated that those skilled in the art will be able to devise various arrangements that, although not explicitly described or shown herein, embody these principles and are included within the scope of this disclosure. As used herein, the term, “or” refers to a non-exclusive or (i.e., and/or), unless otherwise indicated (e.g., “or else” or “or in the alternative”). Additionally, the various embodiments described herein are not necessarily mutually exclusive and may be combined to produce additional embodiments that incorporate the principles described herein. Further, while various exemplary embodiments are described with regard to LGA, it will be understood that the techniques and arrangements described herein may be implemented to facilitate circuit boards with terminals under their bodies in other types of systems that implement multiple types of data processing or data structure.

Some components may include Land Grid Arrays (LGA) to connect to a Printed Circuit Board (PCB). Solder paste may be applied in this case to the PCB while the component is placed onto the correct position. The solder paste thereafter holds the component in the correct position. At a later time, a soldering operation may be performed to fix the component to the PCB.

Some components may have pads with pre-attached solder balls such as in ball grid arrays (BGA's), and these may also need to be placed onto the corresponding pads on the PCB. However with BGAs there may be two alternatives—solder paste or flux, which may include solder-paste without the metallic component. Either the solder paste or the flux may stick the component in place until soldering occurs. Flux alone may be used because the solder of the “solder ball” of the BGA may provide enough solder to result in an electrical connection between the component and the PCB. Once the component is soldered onto the board there may be no visibility or access to the pad which hold the solder joints. The pads may be sheltered under the component.

Frequently, to remove such a component one may heat up the local board area and the component until the heat sufficiently leaks into the pads and melts the solder. Such heating may be accomplished by a technician using a heat gun to heat up the component requiring rework. Also an automated rework machine may be used to heat up and remove the component requiring rework. In either case, heating may be problematic for the reliability of the component (if one were just trying to repair one of the connections under the component) and for nearby components. In certain cases, the heat from reworking one component may render a nearby component defective. Then one has to rework that component by reheating the board in the vicinity of that component and this may damage further components. Thus, there is a need in the art for a reliable fast mechanism of enabling resoldering or reheating of pads without impacting the circuits or damaging components.

Embodiments include one or more thermal rework extensions of pads on the PCBs. Thermal rework extensions may protrude from a component solder attachment point underneath the component to beyond the outline of the body, and may be wide enough to provide a thermal path for the subsequent application of heat through a suitable instrument such as the tip of a soldering tool or de-soldering tool.

As heat is locally applied and flows along the thermally conductive metallic extension, undue heating of the component itself as well as nearby components may be avoided. A bad connection to a single pad may be corrected by the application of heat to a single extension which may remelt the solder to renew the joint. Alternatively, heat may be applied to all the thermal rework extensions simultaneously by an appropriately shaped desoldering tool tip. Also, heat may be applied sequentially to all of the thermal rework extensions. This may have the effect of keeping the heat local and avoiding excessive temperature rise of the component itself.

In some or all of the embodiments, the PCB's may be made by the following process:

Through-holes are produced in a circuit board. The holes may be coated with a conductive material, such as copper, producing a via barrel. Other via construction methods are recognized by those skilled in the art.

Adjacent vias may be entirely covered with etch resist. Etch resist may be a thin layer of a nonconductive polymer which can resist the acids used to remove copper from portions of the PCB. Via pads, via barrels and through-holes may be seen after etching is complete and etch resist is removed. Component pads and solder mask may also be visible. Solder mask may be a thin layer of a nonconductive polymer. Solder mask may prevent the copper portions of the via from oxidizing and prevents unintended solder bridges from accidentally forming on the circuit board. Solder mask may be applied using a silkscreen process. Solder paste may then be applied to a component pad within the boundaries of solder mask.

A portion of solder mask corresponding to a component landing area on a component pad may then be removed. This may be accomplished by etching the solder mask to remove material. In an exemplary embodiment solder mask may be modified using photolithography. However, other processes may be used to remove a portion of solder the mask. Solder paste may be applied to a component pad within the boundaries of the removed portion of solder mask.

A component may be attached to a component pad using reflowed solder paste. Solder mask may act as a part of a barrier between the via pad and component pad, preventing solder bridging from occurring during the attachment process.

Referring now to the drawings, in which like numerals refer to like components or steps, there are disclosed broad aspects of various exemplary embodiments.

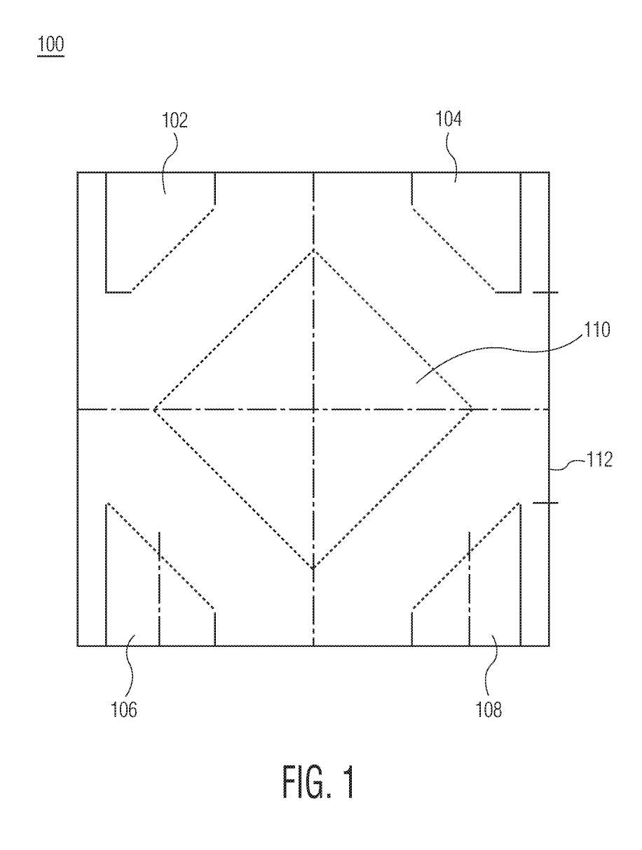

FIG. 1 illustrates a bottom view of an exemplary component 100 for mounting on a PCB. The bottom view of the component 100 depicts a portion of a grid of pads on the component. The component 100 may include corner pads 102-108, center pad 110, and component border 112. The exemplary component 100 may be, for example, 1 mm by 1 mm. Size of the component can be bigger or smaller, varying from one component type to another. Pads 102-108 may be spaced, for example, 0.4 mm apart. Spacing of these pads can be bigger or smaller, varying between different component technologies.

In one embodiment exemplary component 100 may include a surface mount component which is a discrete component. In some cases, this component 100 may be, for example, a resistor, capacitor, inductor, microcontroller, processor, or any integrated circuit. The pads may be connected via conductive copper as required for various layout configurations.

In an exemplary embodiment, a computer aided design (CAD) tool allows the selection of vias and arrangement of the solder mask, component pads, and vias to be substantially automated. The computer aided design tool may automatically identify appropriate spacing and shape of the solder pad so as to allow placement of the surface mount components on the printed circuit board. A CAD tool may also provide instructions to control a machine to manufacture the modified circuit board. Instructions may be exported to the machine or the design tool may directly control the machine.

The CAD instructions may include any Electronic Design Automation tool or technique. For example, mask data preparation (MDP) may be used such as generation of lithography photomasking which may be used to manufacture a circuit or chip. Resolution enhancement techniques to increase the photomask quality may also be used. Similarly, Optimal Proximity Correction (OPC) for compensation of interference and diffraction may be utilized. Mask generation may also be utilized in the manufacturing. Software systems and versions such as Advanced Design System, Altium Designer, CircuitLogix, CircuitMaker, DesignSpark PCB, Pulsonix, SLED and Micro-Cap may be used or programmed for creation and automation of such circuits.

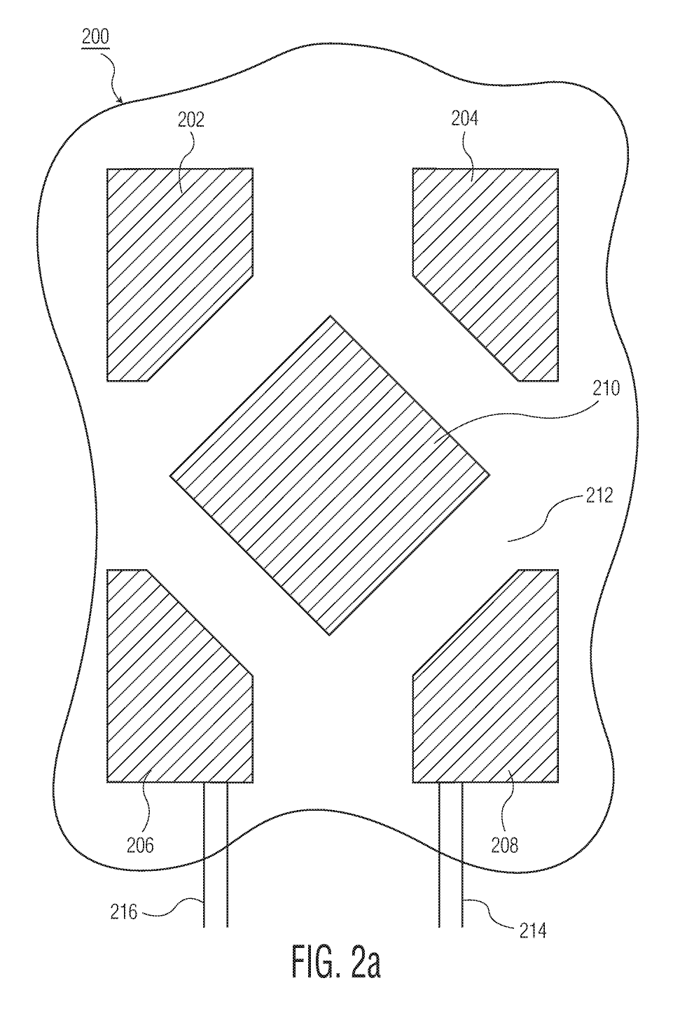

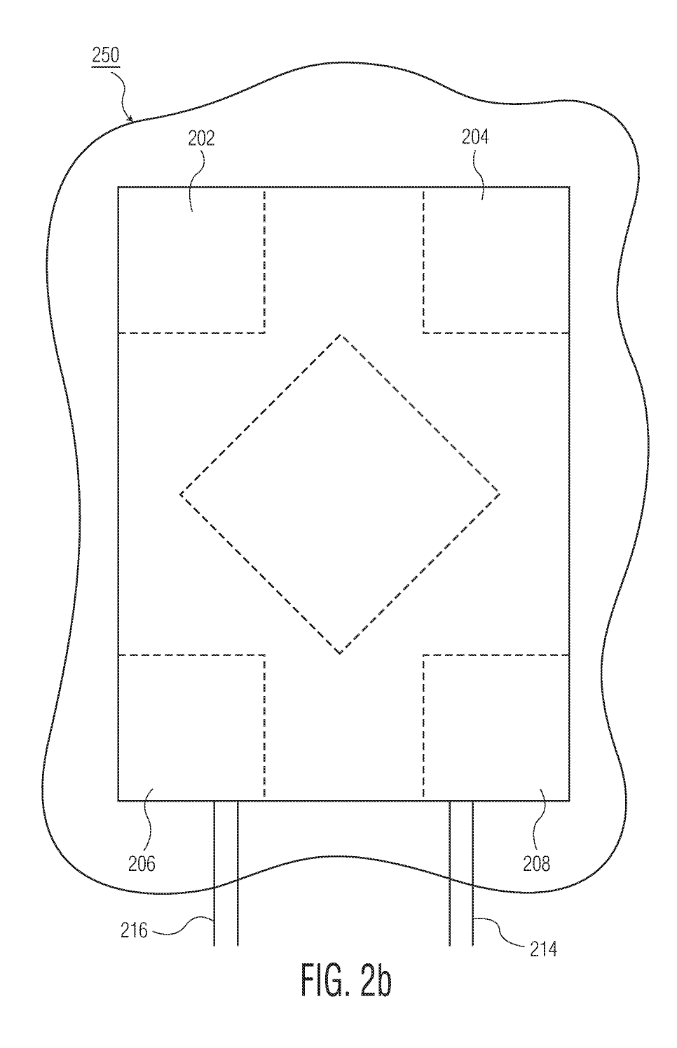

FIG. 2A illustrates a top view of a related art PCB 200. Related PCB 200 may include corner pads 203, 205, 207, and 209 center pad 210, signal lines 214 and 216, and spacing portions 212 between the corner pads 202-208 and the center pad 210. PCB 200 illustrates a typical land pattern used for a specific LGA component. When the component and overlays the PCB, the four corner pads 203, 205, 207, and 209 are within the perimeter of the component to thermal rework extensions 202, 204, 206, and 208, and hence not accessible for touch up by a soldering iron if a defect occurs in any one of the four terminals during assembly. As a result, when defects occur, the component will have to go through the automated rework machine for the repair. The shape of pads corner pads 203, 205, 207, and 209 are exemplary and may be any shape such as a circle, square, triangle, polygon, hexagon, irregular, etc.

FIG. 2B illustrates a top view of a related art PCB with attached component 250. As can be seen, corner pads 203, 205, 207, and 209 do not extend outside the boundaries of component 256 and do not accommodate easy resoldering by a soldering iron.

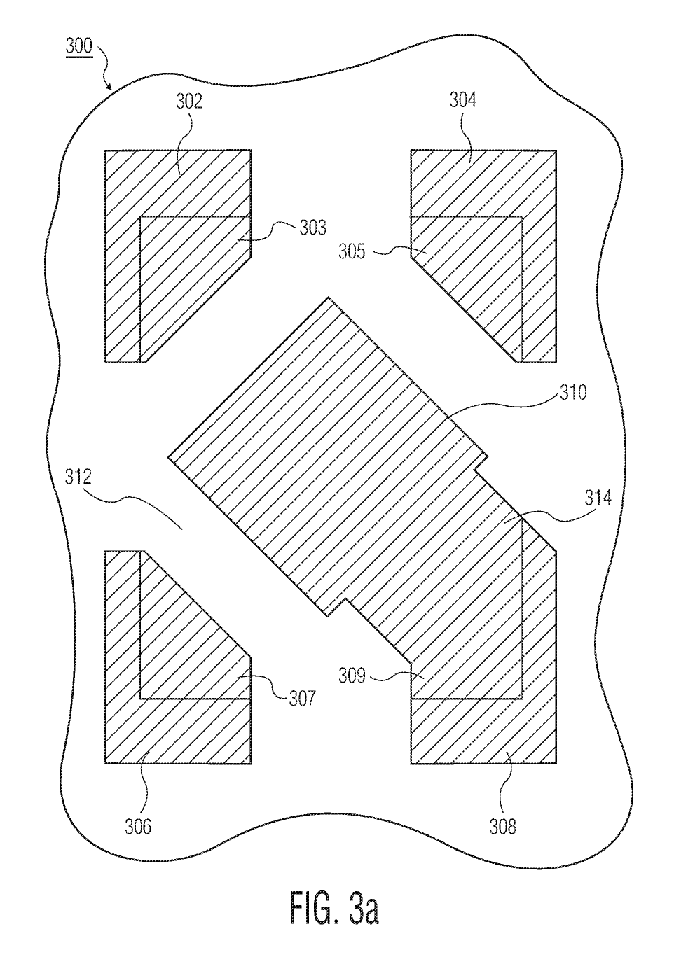

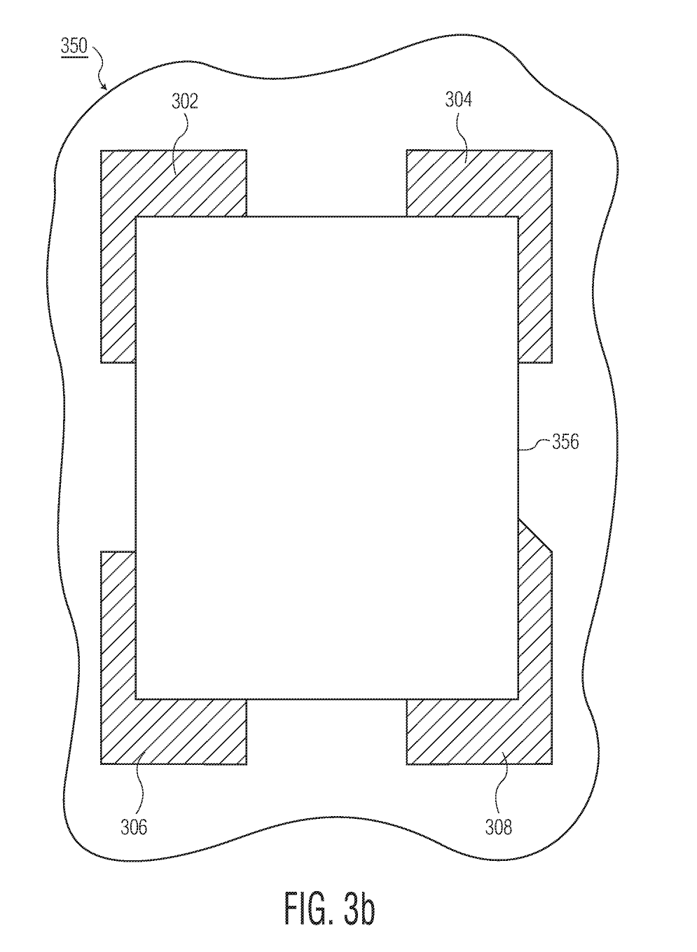

FIG. 3A illustrates a top view of exemplary PCB 300. Exemplary PCB 300 may include corner pads 303, 305, 307, and 309, thermal rework extensions 302, 304, 306, 308, center pad 310, pad extension 314, and spacing portions 312 between the corner pads 302-308 and center pad 310. As illustrated, pad extension 314 may connect center pad 310 to corner pad 308.

FIG. 3A demonstrates one of the approaches of how the corner pads and center pad may be extended for rework. In this scenario, the component may have the center pad 310 and the corner pad 309 which are both connected to the same net. Therefore, connecting the two will not affect the function of the device but allow the center pad to conduct heat through the thermal rework extension 308 for rework. For example, both corner pad 309 and center pad 310 may both need to be connected to Vdd or source voltage or ground. A data line may be connected to both corner pad 309 and center pad 310.

FIG. 3B illustrates a top view of exemplary PCB with attached component 350. Exemplary PCB with attached component 300 may include thermal rework extensions 302, 304, 306, 308 as well as component 356. As can be seen, thermal rework extensions 302, 304, 306, 308 may similarly extend outside the boundaries of component 356 and accommodate easy resoldering by a soldering iron or removal by the application of heat to each of the thermal rework extensions 302, 304, 306, and 308.

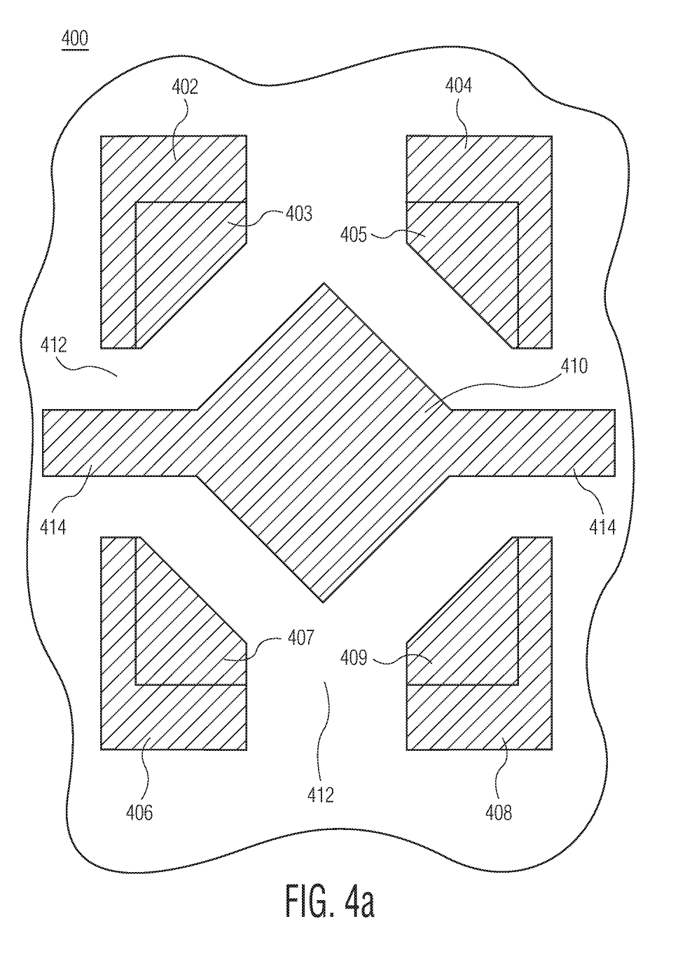

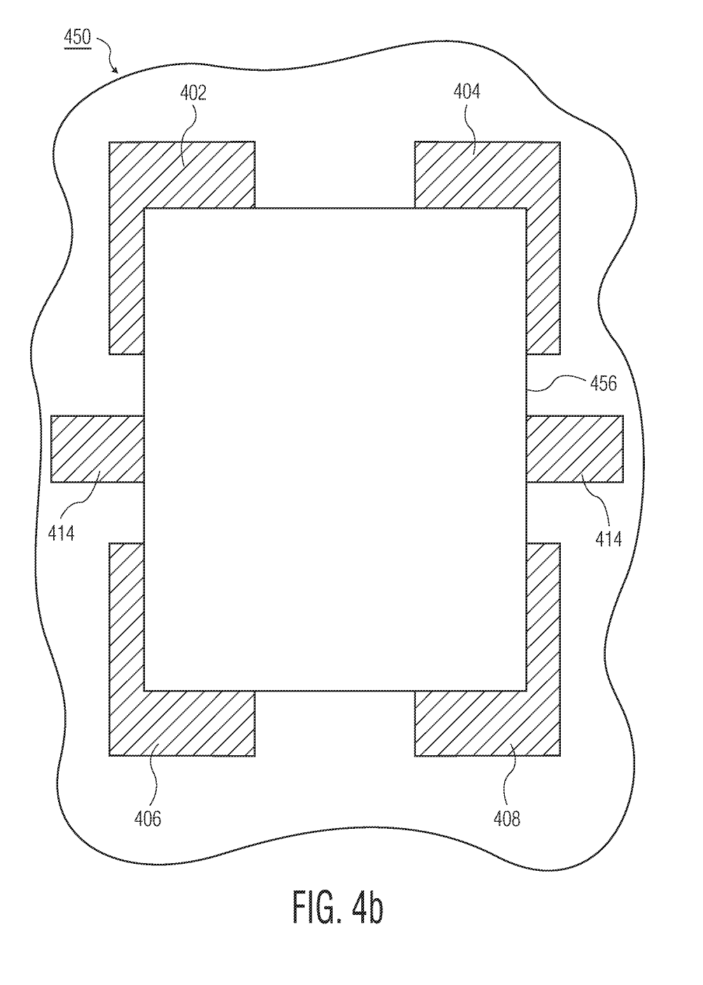

FIG. 4A illustrates a top view of exemplary PCB 400. Exemplary PCB 400 may include thermal rework extensions 402, 404, 406, 408, and 414, corner pads 403, 405, 407, and 409, center pad 410, pad extensions 414, and spacing portions 412 between the corner pads 403, 405, 407, and 409 and center pad 410. The thermal rework extensions 414 extend outside the perimeter of the component which allows the soldering iron to reach either of the pad extensions to conduct heat to the center pad 410 in order to rework the component.

FIG. 4B illustrates a top view of exemplary PCB 450 with attached component. Exemplary PCB 450 may include thermal rework extensions 402, 404, 406, 408, and 414, and component 456.

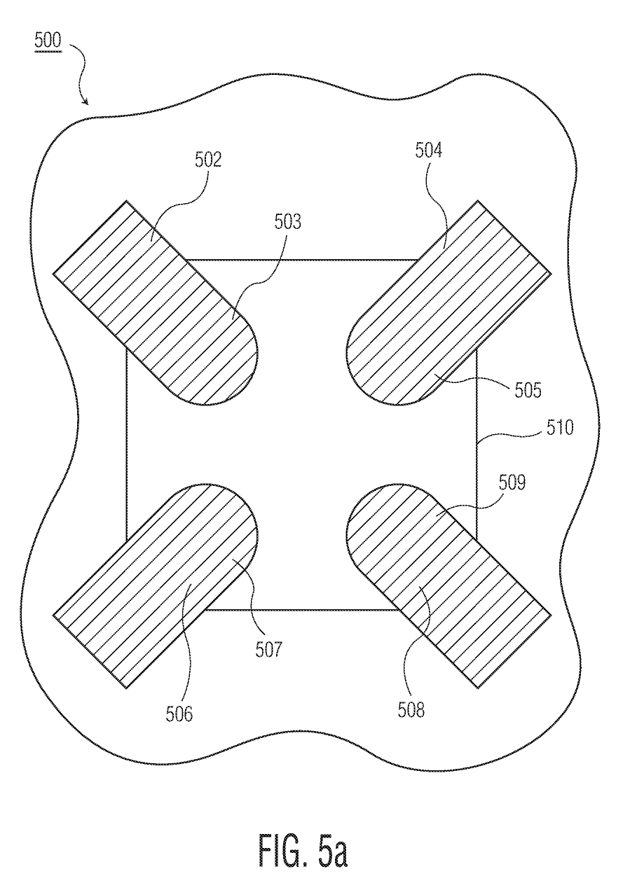

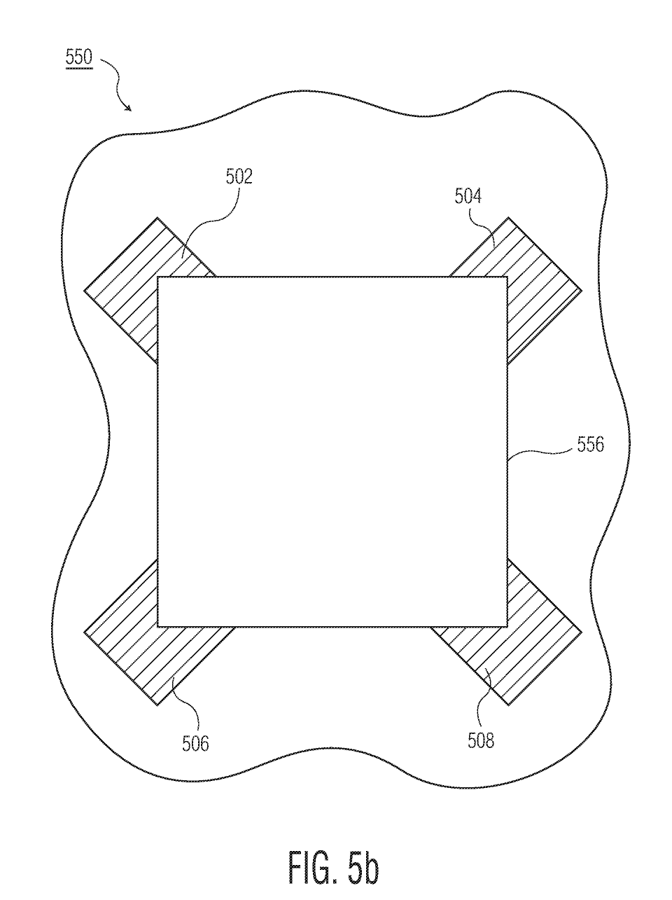

FIG. 5A illustrates a top view of exemplary PCB 500. Exemplary PCB 500 may include thermal rework extensions 502, 504, 506, and 508, corner pads 503, 505, 507, and 509, where the corner pads 503, 505, 507, and 509 extend outward beyond the component boundary 510. FIG. 5A illustrates one of the many approaches for extending the pad outside component boundary 510 with thermal rework extensions, which allows the soldering iron to be applied to the thermal rework extensions to conduct heat in order to melt the solder connections so that the component may be reworked. Corner pads 503, 505, 507, and 509 may be component pads upon which a terminal of a surface-mount component may be soldered.

FIG. 5B illustrates a top view of exemplary PCB 550. Exemplary PCB 550 may include thermal rework extensions 502, 504, 506, and 508 and component 556.

While the figures and descriptions may depict regular circular or rectangular shapes of different elements in exemplary embodiments, it should be understood that alternative shapes may be used such as imperfect polygons and rounded forms. These alternative shapes may be substantially similar to the depicted shapes in area and outline. Further, the various pads that are shown extending outside the component boundary may do so in any direction using any shape as long as a portion of the pads are exposed to the application of a soldering iron or a heating tip.

Thermal rework extensions described above in any of the figures, may include stubs which are rework extensions not connected to signal lines.

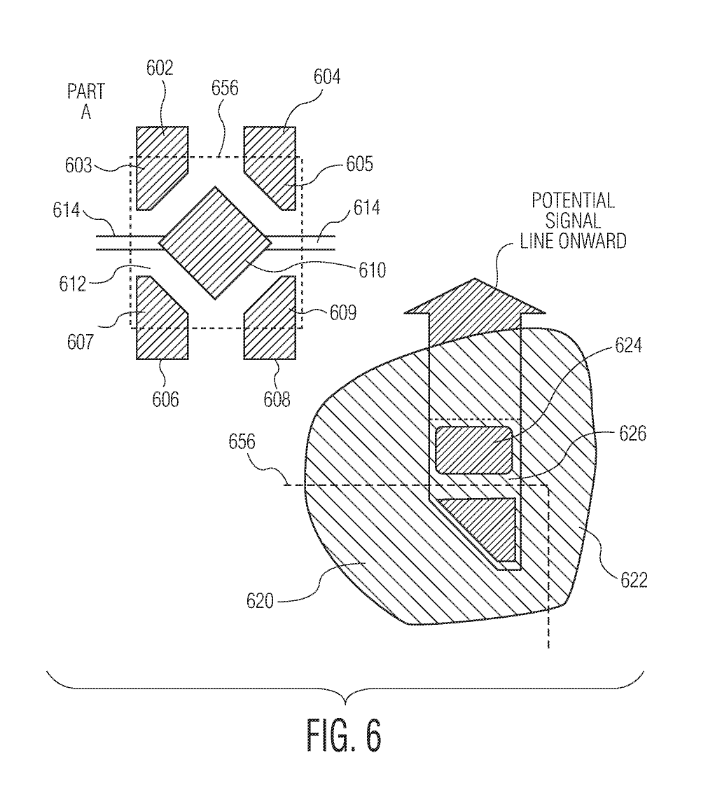

FIG. 6 illustrates another embodiment of a component mounted on a PCB. The PCB may include thermal rework extensions 602, 604, 606, 608, and 614, corner pads 603, 605, 607, and 609, center pad 610, pad extensions 614, and spacing portions 612 between the corner pads 603, 605, 607, and 609 and center pad 610.

An exemplary component outline 656 is superimposed over PCB pads of which the four corner pads possess thermal rework extensions as indicated by way of example with the upper right hand corner pad. The four depicted thermal rework extensions may be stubs as previously described.

FIG. 6 further includes a close-up view of the upper right corner pad the PCB. In normal use the entire surface of the PCB may be covered with a layer of heat resistant plastic material that solder may not adhere to—frequently called solder resist. This layer of solder resist may include apertures 622 (normally accomplished by etching) over each pad which may need to be part of a solder joint. Aperture 622 is an example of this type of aperture. Normally solder paste would be applied within the outline of the aperture and then the component is placed on the board so the solder paste bridges between the PCB pad and the pad or ball on the bottom side of the component. Heat may be applied (to the whole board so as to do all the solder joints relatively simultaneously), the solder paste melts, the heat is removed, the solder hardens, and the requisite permanent connection ensues. The solder resist may serve the purpose of keeping the liquid solder from migrating, confining it to the desired area of the pad. Migration may result in problems such as inadequate joint formation or possibly bridging over to other nearby pads or signal traces that may result in shorts.

As thermal rework extensions are often designed to have heat applied, the presence of solder resist over the top of them is contra-indicated. For rapid, efficient heat transfer from a soldering tool tip a second aperture may be called for. This is illustrated as aperture 624. Signal lines for current PCBs lack aperture 624 as there may be solder resist present for all the reasons that it is normally useful. A portion of the solder resist may be identified as a barrier portion 626. This barrier portion is useful to prevent the solder paste applied within aperture 622 from migrating over to aperture 624 and potentially creating an unreliable connection.

Finally, in the case of the of a stub configuration (i.e., where there is no signal line extending from the thermal rework extension), aperture 624 while desirable is not strictly necessary as enough heat from the soldering tool may eventually pass through the solder resist to allow for the associated connection to be disconnected.

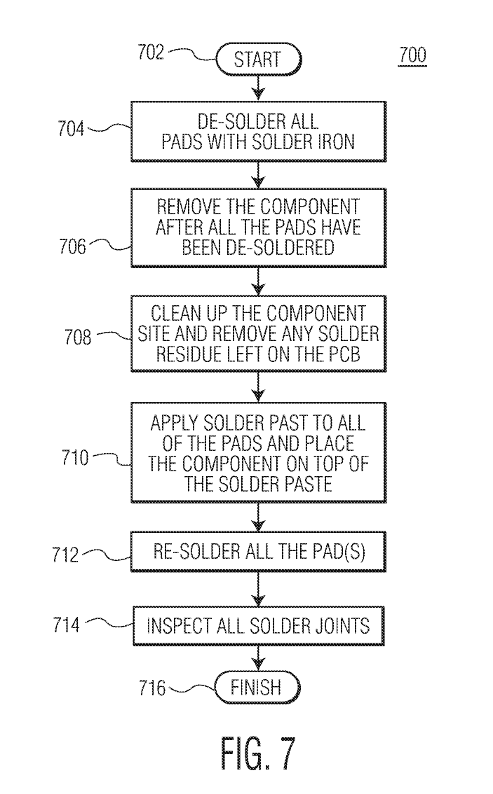

FIG. 7 illustrates exemplary method for resoldering 700. Any of the CAD or manufacturing tools or algorithms described may implement method 700. Similarly, a manufacturing tool may be constructed for programming with the CAD tools to implement method 700. Method 700 may begin in step 702 and proceed to step 704 where the method of manufacturing may de-solder all the pads with a soldering iron by applying heat to the extended pads.

The method 700 may then move to step 706. Alternatively, step 704 may be performed using an appropriately shaped desoldering tool tip that may apply heat to each of the thermal rework extensions simultaneously.

In step 706, the manufacturing tool may remove the component after all the pads have been de-soldered. The component may be any of: resistors, capacitors, inductors, microcontrollers, processors and any integrated circuits. The method 700 may then move to step 708.

In step 708 the manufacturing or CAD tool may clean up or be programmed to clean up the component site and remove any solder residue which is left on the PCB. The method 700 may then move to step 710.

In step 710 the method may apply solder paste to all of the pads and then place the component to the solder paste. The method 700 may then move to step 712.

In step 712, the method may re-solder all of the pads by applying heat to the extended pads. The method 700 may then move to step 714

It should be apparent from the foregoing description that various exemplary embodiments of the invention may be implemented in hardware and/or firmware. Furthermore, various exemplary embodiments may be implemented as instructions stored on a machine-readable storage medium, which may be read and executed by at least one processor to perform the operations described in detail herein. A machine-readable storage medium may include any mechanism for storing information in a form readable by a machine, such as a personal or laptop computer, a server, or other computing device. Thus, a machine-readable storage medium may include read-only memory (ROM), random-access memory (RAM), magnetic disk storage media, optical storage media, flash-memory devices, and similar storage media.

Although the various exemplary embodiments have been described in detail with particular reference to certain exemplary aspects thereof, it should be understood that the invention is capable of other embodiments and its details are capable of modifications in various obvious respects. As is readily apparent to those skilled in the art, variations and modifications can be affected while remaining within the spirit and scope of the invention. Accordingly, the foregoing disclosure, description, and figures are for illustrative purposes only and do not in any way limit the invention, which is defined only by the claims.

What is claimed is:

1. A printed circuit board (PCB) for electrically connecting a surface mount component comprising:
a plurality of metal pads on the surface of one side of the PCB corresponding to connection points on the component,
wherein at least a portion of the plurality of metal pads have stubs which extend outside the boundary of the surface mount component when the surface mount component is mounted to the PCB; and
wherein the stubs have sufficient thermal conductivity to facilitate at least one of the set of dismounting and reattaching of the surface mount component.

2. The PCB of claim 1, wherein the metal pads are arranged in a Ball Grid Array pattern (BGA).

3. The PCB of claim 1, wherein at least one extension is from a center pad of the array.

4. The PCB of claim 1, wherein the metal pads are in a Land Grid Array pattern (LGA).

5. The PCB of claim 1 wherein the stubs are covered by a solder.

6. The PCB of claim 1, wherein the stubs have a solder resist barrier portion between the pads and the stubs.

7. A method of manufacturing a printed circuit board (PCB) assembly for electrically connecting a surface mount component, comprising the steps of:
forming a plurality of metal pads on the surface of one side of the PCB corresponding to connection points on the component, wherein at least a portion of the plurality of metal pads have extensions which extend outside the boundary of the surface mount component when the surface mount component is mounted to the PCB;
wherein the extensions have sufficient thermal conductivity to facilitate at least one of the set of dismounting and reattaching of the surface mount component; and
conductively attaching the component to the plurality of metal pads on the PCB.

8. The method of claim 7, further comprising:
detecting that the component needs at least one connection point to be reattached; and
heating the extensions of the metal pads on the PCB which extend outside the boundaries of the component corresponding to the at least one connection point to reattach the component to the PCB.

9. The method of claim 7, further comprising:
detecting that the component needs to be replaced or reattached;
heating the extensions of the metal pads on the PCB which extend outside the boundaries of the component;
removing the component from the PCB; and
reattaching the component to the PCB by applying heat to the heating extensions of the of the pads which extend from the boundaries of the component.

10. The method of claim 9, further comprising:
cleaning the component and the metal pads on the PCB; and
applying solder to either the metal pads or the component.

11. The method of claim 7, wherein the metal pads are of a Ball Grid Array pattern (BGA).

12. The method of claim 7, wherein one of the metal pads is a center pad.

13. The method of claim 7, wherein the metal pads are in a Bottom Terminated Component pattern (BTC).

14. The method of claim 12, wherein the center pad extends outside the boundary of the component in two different directions.

15. A computer aided design tool implemented on a computing device for accommodating a resoldering of a land grid array printed circuit board (PCB) for use with mounting a component comprising:
a design tool mode configured to identify a placement of components on the PCB and to create a corresponding array of metal pads on one side of the PCB, wherein the metal pads extend outside the boundary of the component when the component is mounted to the PCB;
a design tool mode configured to create thermal connections between the metal pads and the extensions have a solder resist barrier portion between the pads and the extensions, and the extensions are also portions of signal carrying lines.

16. A printed circuit board (PCB) for electrically connecting a surface mount component comprising:
a plurality of metal pads on the surface of one side of the PCB corresponding to connection points on the component, wherein at least a portion of the plurality of metal pads have extensions which extend outside the boundary of the surface mount component when the surface mount component is mounted to the PCB and wherein the extensions have sufficient thermal conductivity to facilitate at least one of the set of dismounting and reattaching of the surface mount component;
a signal line connected to one of the plurality of extensions; and
a layer of solder resist covering the signal line, wherein the layer of solder resist has an aperture over the extensions.

17. The PCB of claim 16 wherein the metal pads are arranged in a Ball Grid Array pattern (BGA).

18. The PCB of claim 16, wherein at least one extension is from a center pad of the array.

19. The PCB of claim 16, wherein the metal pads are in a Land Grid Array pattern (LGA).

20. The PCB of claim 16, wherein the stubs have a solder resist barrier portion between the pads and the stubs.
